(19) United States
(12) Patent Application Publication
(10) Pub. No.: US 2026/0164565 A1
(43) Pub. Date: Jun. 11, 2026

(54) CONDUCTIVE THROUGH VIAS AND METHODS OF FORMING CONDUCTIVE THROUGH VIAS

(71) Applicant: Toyota Motor Engineering & Manufacturing North America, Inc., Plano, TX (US)

(72) Inventors: Feng Zhou, Ann Arbor, MI (US); Tianzhu Fan, Houston, TX (US); Shailesh N. Joshi, Ann Arbor, MI (US); Yanghe Liu, Ann Arbor, MI (US); Ercan Mehmet Dede, Ann Arbor, MI (US)

(21) Appl. No.: 18/975,564

(22) Filed: Dec. 10, 2024

(51) Int. Cl. H05K 3/40; H05K 1/11

(52) U.S. Cl. CPC H05K 3/4053; H05K 1/115; H05K 2201/0323; H05K 2201/09563; H05K 2203/0763; H05K 2203/0783

(57) ABSTRACT

A method for fabricating a conductive through via includes mixing metal formate with a solvent and forming a metal formate—solvent solution, adjusting a concentration of the metal formate—solvent solution and forming a refined metal formate—solvent solution, and mixing the refined metal formate—solvent solution with metal particles and forming a metal particle—metal formate slurry. The method also includes filling a via in a substrate with the metal particle—metal formate slurry and low temperature sintering the metal particle—metal formate slurry and forming a large diameter conductive through via in the substrate.

### TECHNICAL FIELD

The present disclosure relates to vias, and particularly to conductive through vias in printed circuit boards.

### BACKGROUND

Printed circuit boards (PCBs) are typically used for mechanical support and electrical connection of electronic components using conductive pathways of copper sheets laminated onto a non-conductive substrate and multi-layer PCBs provide higher capacity and/or density of electronic components in a smaller footprint by incorporating two or more layers. However, the design and/or forming of vertical interconnect accesses (vias) in multilayer PCBs can be difficult.

The present disclosure addresses issues related to the forming of vias in multi-layer PCBs and other issues related to vias.

### SUMMARY

This section provides a general summary of the disclosure and is not a comprehensive disclosure of its full scope or all of its features.

In one form of the present disclosure, a method for fabricating a conductive through via includes mixing metal formate with a solvent and forming a metal formate—solvent solution, adjusting a concentration of the metal formate—solvent solution and forming a refined metal formate—solvent solution, mixing the refined metal formate—solvent solution with metal particles and forming a metal particle—metal formate slurry, filling a via in a substrate with the metal particle—metal formate slurry, and low temperature sintering the metal particle—metal formate slurry to form a large diameter conductive through via in the substrate.

In another form of the present disclosure, a method for fabricating a conductive through via in a circuit board includes mixing copper formate with a solvent and forming a copper formate—solvent solution, adjusting a concentration of the copper formate—solvent solution and forming a refined copper formate—solvent solution, mixing the refined copper formate—solvent solution with metal particles and forming a metal particle—copper formate slurry, filling a via in a circuit board substrate with the metal particle—copper formate slurry, and low temperature sintering the metal particle—copper formate slurry to form a large diameter conductive through via in the circuit board substrate.

In still another form of the present disclosure, a method for fabricating a conductive through via in a circuit board includes mixing copper formate with a solvent and forming a copper formate—solvent solution, adjusting a concentration of the copper formate—solvent solution and forming a refined copper formate—solvent solution, mixing the refined copper formate—solvent solution with copper particles and forming a copper particle—copper formate slurry, filling a via in a circuit board substrate with the copper particle—copper formate slurry, and low temperature sintering the copper particle—copper formate slurry to form a large diameter conductive through via in the circuit board substrate.

Further areas of applicability and various methods of enhancing the above technology will become apparent from the description provided herein. The description and specific examples in this summary are intended for purposes of illustration only and are not intended to limit the scope of the present disclosure.

### BRIEF DESCRIPTION OF THE DRAWINGS

The present teachings will become more fully understood from the detailed description and the accompanying drawings, wherein:

FIG. 1 is a side cross-sectional view of a chip-embedded printed circuit board (PCB) with conductive through vias according to one form of the present disclosure;

FIG. 2 is a side cross-sectional view of a chip-embedded PCB with conductive through vias according to another form of the present disclosure;

FIG. 3A illustrates a step in forming conductive through vias shown in FIG. 1 and/or FIG. 2;

FIG. 3B illustrates another step in forming conductive through vias shown in FIG. 1 and/or FIG. 2;

FIG. 3C illustrates still another step in forming conductive through vias shown in FIG. 1 and/or FIG. 2;

FIG. 3D illustrates yet another step in forming conductive through vias shown in FIG. 1 and/or FIG. 2;

FIG. 3E illustrates still yet another step in forming conductive through vias shown in FIG. 1 and/or FIG. 2;

FIG. 3F illustrates a step in forming conductive through vias shown in FIG. 1 and/or FIG. 2;

FIG. 3G illustrates another step in forming conductive through vias shown in FIG. 1 and/or FIG. 2;

FIG. 4A illustrates a step in forming conductive through vias shown in FIG. 1 and/or FIG. 2;

FIG. 4B illustrates another step in forming conductive through vias shown in FIG. 1 and/or FIG. 2;

FIG. 4C illustrates still another step in forming conductive through vias shown in FIG. 1 and/or FIG. 2;

FIG. 4D illustrates yet another step in forming conductive through vias shown in FIG. 1 and/or FIG. 2;

FIG. 4E illustrates still yet step in forming conductive through vias shown in FIG. 1 and/or FIG. 2;

FIG. 5A illustrates a step in forming a conductive through via shown in FIG. 1 and/or FIG. 2;

FIG. 5B illustrates another step in forming a conductive through via shown in FIG. 1 and/or FIG. 2;

FIG. 5C illustrates still another step in forming a conductive through via shown in FIG. 1 and/or FIG. 2; and

FIG. 6 is a flow chart for a method of forming a conductive through via according to the teachings of the present disclosure.

It should be noted that the figures set forth herein are intended to exemplify the general characteristics of the methods and devices among those of the present technology, for the purpose of the description of certain aspects. The figures may not precisely reflect the characteristics of any given aspect and are not necessarily intended to define or limit specific forms or variations within the scope of this technology.

### DETAILED DESCRIPTION

The present disclosure provides conductive through vias in printed circuit boards (PCBs) and methods of forming conductive through vias in PCBs. As used herein, the term “via”, also known as “vertical interconnect access”, refers to hole/aperture extending through a PCB and the phrase “conductive through via” refers to a via at least partially filled with an electrically conductive material (e.g., copper) such that electrical signals pass between different PCB layers of a multi-layer PCB through the conductive through vias. In some variations, the conductive through vias according to the teachings of the present disclosure extend through two or more PCBs of a chip-embedded PCB. As used herein, the phrase “chip-embedded PCB” refers to a multi-layer PCB module or unit with two or more PCB substrates (layers), two or more power semiconductor devices (also known as a “chip” and referred to herein simply as “power device” or “power devices”), control/drive/protection electronic circuitry, and passive components. Also, as used herein, the phrase “power device” refers to a semiconductor device used as a switch or rectifier in power electronics.

The conductive through vias are formed by filling vias with a metal particle—metal formate slurry and sintering the metal particle—metal formate slurry. That is, the conductive through vias are sintered metal particle—metal formate vias (also referred to herein simply as “metal—metal formate via(s)”), where the term “sinter” or “sintered” as used herein refers to heating a slurry of metal particles mixed with a metal formate—solvent solution such that the metal formate chemically reduces and forms bonds between the metal particles without the metal particles melting. In some variations, the sintered metal—metal formate vias are sintered without pressure, other than atmospheric pressure, applied to the metal—metal formate vias during sintering thereof. And in at least one variation, the sintered metal—metal formate vias are sintered are sintering in an oxygen-free environments. As used herein, the phrase “oxygen-free environment” refers to a partial pressure of oxygen less than about 10⁻⁵ atmospheres. In some variations, the oxygen-free environments according to the teachings of the present disclosure have a partial pressure of oxygen less than about 10⁻⁶ atmospheres and in at least one variation he oxygen-free environments according to the teachings of the present disclosure have a partial pressure of oxygen less than about 10⁻⁷ atmospheres.

In some variations, the metal—metal formate slurry is sintered at low temperatures to form a conductive through via. Stated differently, conductive through vias, according to the teachings of the present disclosure, are low-temperature sintered metal—metal formate vias. As used herein, the phrase “low-temperature sintered” refers to a temperature used to form a sintered metal—metal formate via, according to the teachings of the present disclosure, that it is at least 100 ° C. less than a temperature used to sinter the same metal particles according to traditional sintering techniques. Accordingly, the conductive through vias according to the teachings of the present disclosure can be sintered at temperatures that are lower than traditional sintering temperatures for known metal layers or metal vias.

The metal particles in the sintered slurry layer can be selected in order to provide a conductive through via with a desired value of heat transfer and/or desired value of electrical conductivity. For example, the metal particles can be copper particles, copper alloy particles, aluminum particles, or aluminum alloy particles, among others. Also, the metal particles can be nanoparticles with an average diameter between about 100 nanometers (nm) and about 900 micrometers (μm). In some variations, the metal particles have an average diameter between about 100 nm and about 200 nm, between about 200 nm and about 300 nm, between about 300 nm and about 400 nm, between about 400 nm and about 500 nm, between about 500 nm and about 600 nm, between about 600 nm and about 700 nm, between about 700 nm and about 800 nm, and/or between about 800 nm and about 900 nm.

In some variations, the slurry further includes a filler such that heat transfer and/or electrical conductivity of the conductive through vias is/are altered or adjusted relative the conductive through vias not including the filler. Non-limiting examples of a filler include graphene and carbon nanotubes, among others. As used herein, the term “graphene” refers to 2D layers of carbon atoms and the phrase “carbon nanotubes” refers to cylindrical tubes formed from a sheet or sheets of graphene.

In some variations, the slurry is synthesized such that a uniform sintered metal—metal formate via, with or without a filler, is provided. And as used herein, the phrase “uniform sintered metal—metal formate via” refers to sintered metal—metal formate slurry via without a delaminated layer of excess reduced metal formate. Accordingly, the conductive through vias according to the teachings of the present disclosure have a generally uniform and smooth outer surface and a generally uniform particle packing density. In some variations, the slurry is synthesized such that the amount of metal formate in the slurry is carefully controlled, e.g., reduced, such that sufficient metal formate is present for sintering of the metal particles together and yet excess metal formate is not present to form delaminated layers of reduced metal formate in or on a sintered metal—metal formate via.

In some variations, the conductive through vias according to the teachings of the present disclosure are large diameter conductive through vias where large diameter conductive through vias as used herein refers to conductive through vias with an average diameter greater than 1.0 millimeter. For example, and in contrast to traditional conductive through vias having average diameters up to about 0.8 mm, large diameter conductive through vias according to the teachings of the present disclosure can have an average diameter between about 1.0 mm and about 20.0 mm. In some variations, an average diameter of large diameter conductive through vias according to the teachings of the present disclosure is between about 1.0 μm and about 2.0 mm, between about 2.0 mm and about 3.0 mm, between about 3.0 mm and about 4.0 mm, between about 4.0 mm and about 5.0 mm, between about 5.0 mm and about 6.0 mm, between about 6.0 mm and about 7.0 mm, between about 7.0 mm and about 8.0 mm, between about 8.0 mm and about 9.0 mm, between about 9.0 mm and about 10.0 mm, between about 10.0 mm and about 15.0 mm, or between about 15.0 mm and 20.0 mm. And it should be understood that large diameter conductive through vias cannot be desirably formed using traditional conductive through vias techniques such as electrolytic deposition, i.e., electroplating copper vias with large diameters and/or depths can be challenging due to limitations inherent in the process such as non-uniform deposition, electrolyte flow limitation, high aspect ratios, and internal stress of deposited vias. It should also be understood that such large diameter conductive vias provide enhanced heat transfer between PCB layers and/or between a power device and a heat sink of a chip-embedded PCB.

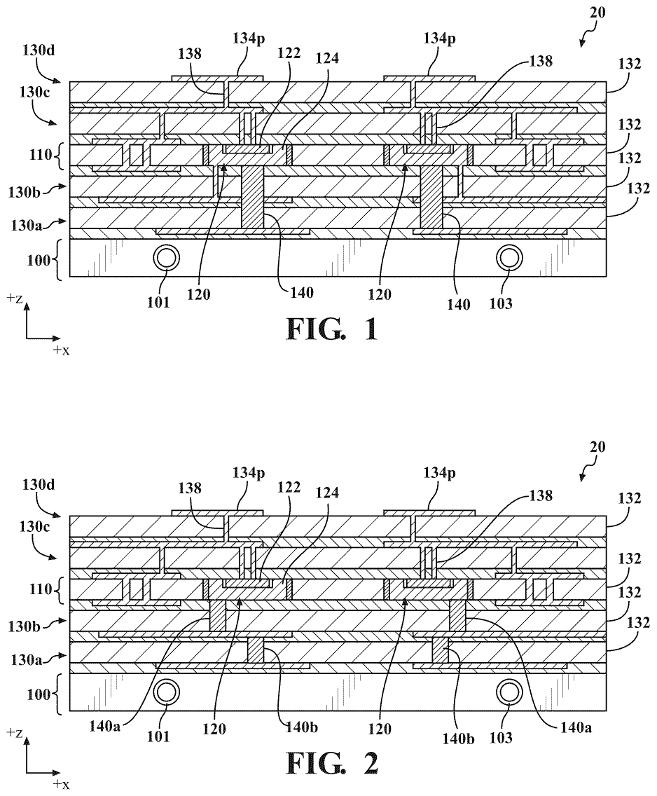

Referring now to FIG. 1, a cross-sectional view of a chip-embedded PCB 10 according to one form of the present disclosure is shown. The chip-embedded PCB 10 includes a cold plate 100 (not shown in cross-section in the figures), a core layer 110, a plurality of circuit board layers 130a-130d (collectively referred to herein as “circuit board layers 130”), and one or more large diameter conductive through vias 140. In some variations, at least one the large diameter conductive through vias 140 extends between the core layer 110 and the circuit board layer 130a. As used herein, the phrase “cold plate” refers to a device that removes heat from electronic components and other surfaces with high heat loads. That is, a cold plate provides localized cooling of power electronics, e.g., by transferring heat from the power electronics to a remote heat exchanger and in at least one variation, the one or more large diameter conductive through vias 140 provide enhanced transfer from the core layer 110 to the cold plate 100. In some variations, the cold plate 100 is a fluid (e.g., water) cooled cold plate 100 with a fluid inlet 101 and a fluid outlet 103. In other variations, the cold plate 100 is a two-phase cooling device, a vapor chamber, or an air-cooled heat sink.

In some variations, the one or more large diameter conductive through vias 140 have a generally uniform diameter (x-direction) along a length (z-direction) thereof, while in other variations the one or more large diameter conductive through vias 140 have a generally tapered diameter along a length thereof. And in at least one variation, the one or more large diameter conductive through vias 140 have a first length with a first average diameter and a second length, different than the first length, with a second average diameter different than the first average diameter.

The core layer 110 includes a substrate 112 with two or more bare die—heat spreader assemblies 120 embedded therein. Each of the bare die—heat spreader assemblies 120 includes a bare die 122 (i.e., a power device) bonded to and in thermal and electrical contact with a heat spreader 124. Each of the circuit board layers 130 includes a circuit board substrate 132 (also referred to herein as “layer 132”), control/drive/protection electronic circuitry 134p (also referred to herein simply as “predefined conductive pattern 134p”), and one or more small diameter conductive through vias 138 and/or one or more large diameter conductive through vias 140 extending between a lower (−z direction) surface and an upper (+z direction) surface of a given circuit board substrate 132. As used herein, the phrase “small diameter conductive through vias” refers to a conductive though via with an average diameter less than or equal to 0.8 mm. Non-limiting examples of the circuit board substrate 132 include an FR4 substrate, a silicon substrate, a glass substrate, a diamond substrate, a low-temperature co-fired ceramics (LTCC) substrate, and a high-temperature co-fired ceramics (HTCC) substrate, among others, and where the term or acronym “FR4” refers to a composite material of woven fiberglass in a flame-retardant epoxy resin.

In some variations, one or more of the small diameter conductive through vias 138 is in direct contact with a bare die 122 (i.e., a power device) of a bare die—heat spreader assembly 120 and one or more of the large diameter conductive through vias 140 is in direct contact with a heat spreader 124 of a bare die—heat spreader assembly 120. As observed from FIG. 1, a single large diameter conductive through via 140 extends linearly through the circuit board layer 130b and into direct contact with the circuit board layer 130b. Stated differently, the large diameter conductive through vias 140 extend directly (linearly) from a lower (−z direction) surface of the heat spreaders 124 to the circuit board layer 130b. In this manner electrical signals can be transmitted to and received from the bare dies 122 of the bare die—heat spreader assemblies 120 such that data and instructions provide for the exchange of information between the bare dies 122 and other electrical components. In addition, the large diameter conductive through vias 140 provide enhanced heat transfer from the heat spreaders 124, and thus the bare dies 122, to the cold plate 100. In some variations, a large diameter conductive through via 140 is included as part of the chip-embedded PCB 10 for heat (thermal) transfer alone, i.e., traditional vias 138 are used for sending and receiving electrical signals to the bare dies 122 and the large diameter conductive through vias 140 are electrically insulated from the bare dies 122 but do provide heat transfer therefrom. Stated differently, in some variations the large diameter conductive through via 140 is an exclusive thermal conductive through via 140.

Referring now to FIG. 2, a cross-sectional view of a chip-embedded PCB 20 according to another form of the present disclosure is shown. The chip-embedded PCB 20 includes the cold plate 100, the core layer 110 and the plurality of circuit board layers 130a-130d. However, and unlike the chip-embedded PCB 10, large diameter conductive through vias 140 between the bare die—heat spreader assemblies 120 and the circuit board layer 130a are in sections. For example, a first large diameter conductive through via 140a extends from a bare die—heat spreader assemblies 120 through the circuit board layer 130b and a second large diameter conductive through via 140b extends through the circuit board layer 130a. And similar to the large diameter conductive through vias 140 illustrated in FIG. 1 and discussed above, the first large diameter conductive through via 140a and the second large diameter conductive through via 140b provided enhanced heat transfer between the bare dies 122 and the cold plate 100. In some variations, the first large diameter conductive through via 140a has a first diameter and the second large diameter conductive through via 140b has a second diameter that is generally the same as the first diameter. In other variations, the first large diameter conductive through via 140a has a first diameter and the second large diameter conductive through via 140b has a second diameter that is not the same (equal) as the first diameter.

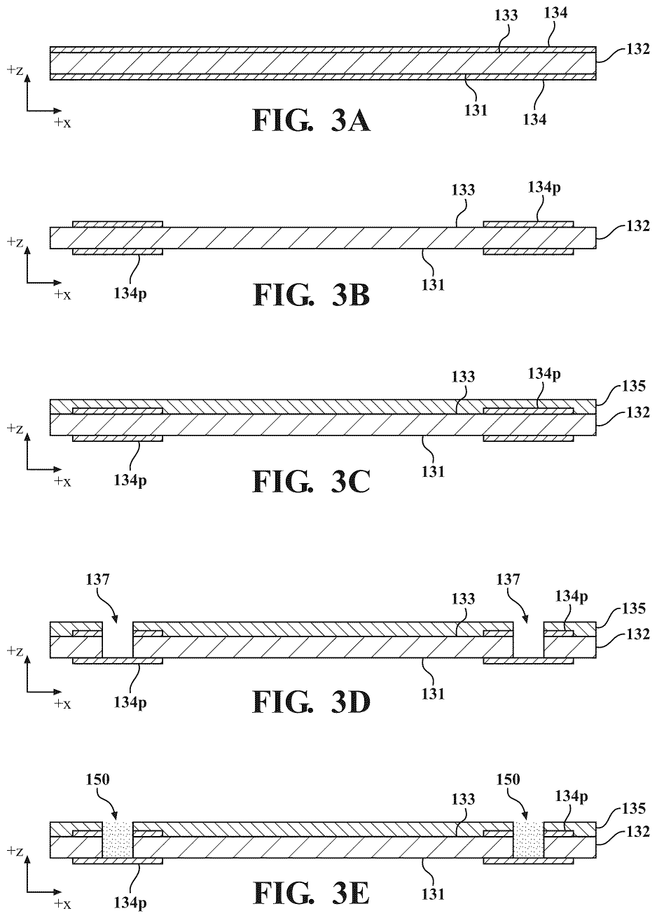

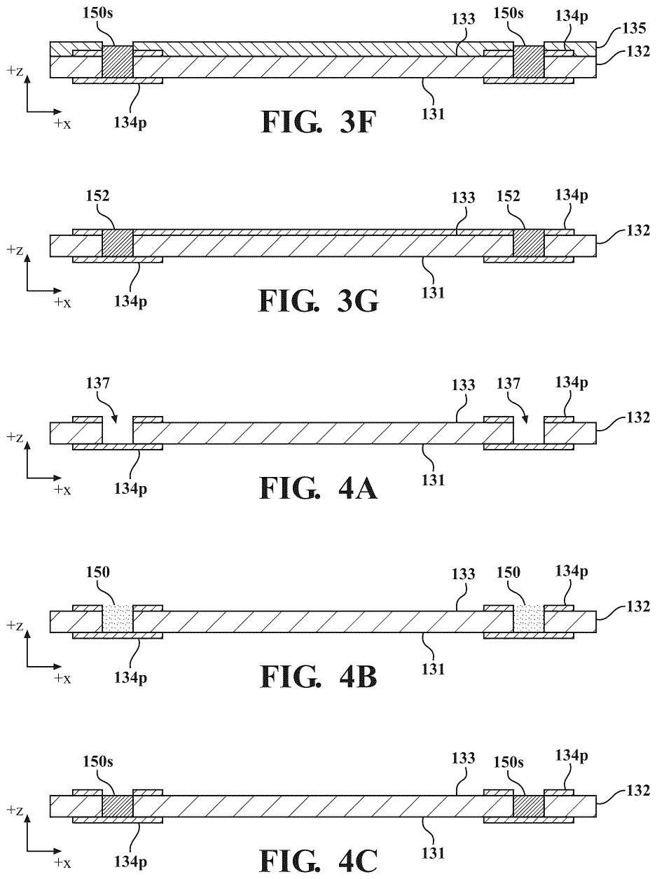

Referring to FIGS. 3A-3G, steps for the manufacture of a circuit board layer 130 according to one method of the present disclosure are illustrated. And while the circuit board layer 130 illustrated in FIGS. 3A-3G does not have the same structure as circuit board layers 130a or 130b shown in FIGS. 1-2, it should be understood that the steps illustrated and discussed in reference to FIGS. 3A-3G below can be applied to circuit board layers 130a, 130b, and other circuit board layers used to fabricate chip-embedded PCBs.

Referring to FIG. 3A, one step of manufacturing the circuit board layer 130 includes forming an electrically conductive layer 134 (also referred to herein simply as “conductive layer 114”) on a first surface 131 and/or on a second surface 133 of a circuit board substrate 132. The circuit board substrate 132 has a predefined thickness (z-direction), width (x-direction), and length (y-direction). In some variations, the circuit board substrate 132 has a thickness between about 0.05 millimeters (mm) and about 5.0 mm. The conductive layer 134 is formed or applied to the circuit board substrate 132 using any method or technique known or yet to be discovered, including chemical vapor deposition (CVD), physical vapor deposition (PVD), sputtering coating, directed bonded copper (DBC), direct plated copper (DPC), stencil/vacuum plating, screen printing, and inkjet printing, among others. Also, the conductive layer 134 is formed from an electrically conducting material (e.g., copper (Cu), silver (Ag), or alloys thereof) and in some variations has a predefined thickness between about 35 micrometers (μm) and about 105 μm.

Referring to FIGS. 3B-3C, additional steps for the manufacture of the circuit board layer 130 include etching the conductive layer 134 to form a predefined conductive pattern 134p on the first surface 131 and/or on the second surface 133 of the circuit board substrate 132 (FIG. 3B) and forming a dielectric layer 135 on the first surface 131 and/or on the second surface 133 (not shown), and on the predefined conductive pattern 134p if present (FIG. 3C). In some variations, etching the conductive layer 134 to form the predefined conductive pattern 134p includes applying resist to the first surface 131 and/or the second surface 133, exposure and development of the resist, etching, rinsing and cleaning, inspection and quality control, and surface finishing of the exposed circuit board substrate 132 and/or the predefined conductive pattern 134p. And in at least one variation, forming the dielectric layer 135 on the first surface 131 and/or on the second surface 133, and on the predefined conductive pattern 134p if present, includes laminating the dielectric layer 135 on the circuit board substrate 132 and predefined conductive pattern 134p using a high temperature—high pressure process.

Referring to FIGS. 3D-3F, additional steps for the manufacture of the circuit board layer 130 include forming large diameter vias 137 through the dielectric layer 135, the predefined conductive pattern 134p if present, and the circuit board substrate 132 (FIG. 3D), filling the large diameter vias 137 with a metal—metal formate slurry 150 (FIG. 3E), and low temperature (LT) sintering the metal—metal formate slurry 150 to form LT sintered metal particle—metal formate 150s within the large diameter vias 137 (FIG. 3F). In some variations, forming the large diameter vias 137 through the dielectric layer 135, the predefined conductive pattern 134p if present, and the circuit board substrate 132 includes alignment, drilling (e.g., laser or mechanical drilling) vias through the dielectric layer 135, predefined conductive pattern 134p (if present) and the circuit board substrate 132. And while FIG. 3D illustrates the large diameter vias 137 having been formed through an upper (+z direction) predefined conductive pattern 134p on the second surface 133 of the circuit board substrate 132, but not extending through a lower (−z direction) predefined conductive pattern 134p on the first surface 131, it should be understood that in some variations, the large diameter vias 137 is formed through the lower predefined conductive pattern 134p.

In least one variation, filling the large diameter vias 137 with the metal—metal formate slurry 150 includes using a via filling technique such as use of a mechanical injector. And as observed in FIG. 3F, in some variations LT sintering the metal—metal formate slurry 150 results in a reduced height (z-direction) of the LT sintered metal particle—metal formate 150s compared to the height of the height of the metal—metal formate slurry 150 in the vias before LT sintering (FIG. 3E).

Referring to FIG. 3G, an additional step includes removing a portion of the dielectric layer 135 such that a conductive through via 152 is formed within the circuit board layer 130. In some variations, the height (z-direction) of the sintered metal particle—metal formate 150s is generally equal to the height of the adjacent predefined conductive pattern 134p such that additional processing is not needed for forming the conductive through vias 152. While in other variations, the height of the sintered metal particle—metal formate 150s is generally greater than the height of the adjacent predefined conductive pattern 134p such that additional processing is needed, for example grinding or polishing an upper (+z direction) surface of the sintered metal particle—metal formate 150s until the upper surface is generally at the same height as an upper surface of the predefined conductive pattern 1349 and the conductive through vias 152 are formed.

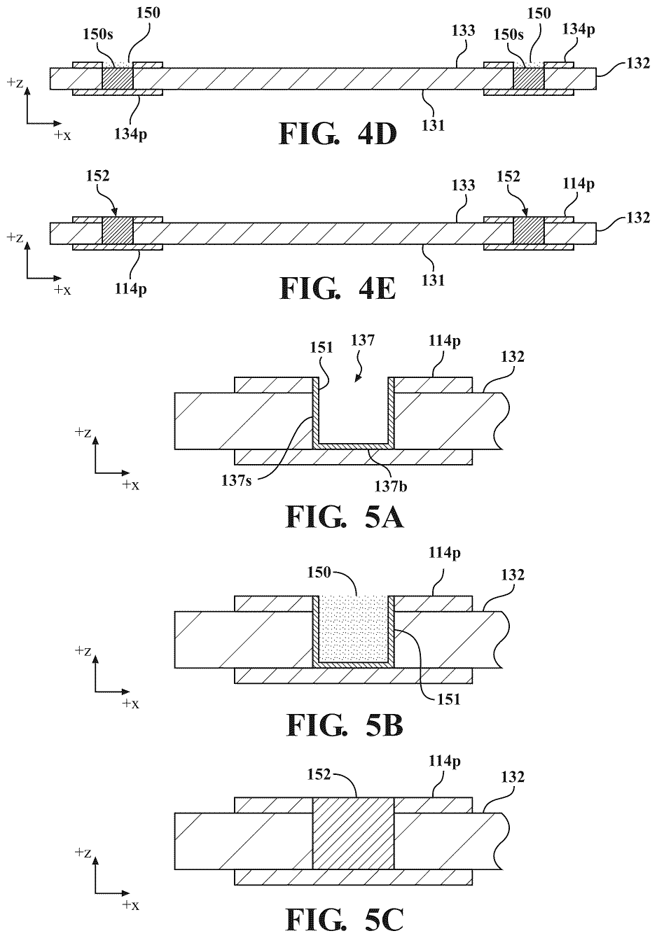

Referring to FIGS. 4A-4E, steps for the manufacture of a circuit board layer 130 according to another method of the present disclosure are illustrated. Particularly, and with reference to FIG. 4A, large diameter vias 137 are formed through a circuit board substrate 132 having a predefined conductive pattern 134p thereon, but not having a dielectric layer thereon. That is, a conductive layer 114 is formed on a first surface 131 and/or on a second surface 133 of a circuit board substrate 132 as described above with respect to FIG. 3A, and the conductive layer 134 is etched to form a predefined conductive pattern 134p on the first surface 131 and/or on the second surface 133 of the circuit board substrate 132 as described above with respect to FIG. 3B. Then, the large diameter vias 137 are formed though the circuit board substrate 132 and a predefined conductive pattern 134p if present. And while FIG. 4A illustrates the large diameter vias 137 having been formed through an upper (+z direction) predefined conductive pattern 134p on the second surface 133 of the circuit board substrate 132, but not extending through a lower (−z direction) predefined conductive pattern 134p on the first surface 131, it should be understood that in some variations, the large diameter vias 137 is formed through the lower predefined conductive pattern 134p.

Referring to FIGS. 4B-4C, the large diameter vias 137 are filled with a metal—metal formate slurry 150 (FIG. 4B), and LT sintering the metal—metal formate slurry 150 to form LT sintered metal particle—metal formate 150s within the large diameter vias 137 is shown in FIG. 4C. And as observed from FIG. 4C, LT sintering of the metal—metal formate slurry 150 results in a decrease in the height (z direction) of the LT sintered metal particle—metal formate 150s compared to the metal—metal formate slurry 150.

Accordingly, and with reference to FIGS. 4D-4E, additional metal—metal formate slurry 150 is added to large diameter vias 137, i.e., on top of the LT sintered metal particle—metal formate 150s, and LT sintering of the additional metal—metal formate slurry 150 is performed such that the conductive through vias 152 are formed. And while not shown in the figures, ion some variations polishing and/or grinding of the upper (+z direction) surface of the upper predefined conductive pattern 134p and/or the conductive through vias 152 is performed such that a flat, planar, and/or smooth upper surface of the upper predefined conductive pattern 134p and the conductive through vias 152 is provided. In addition, and while FIGS. 4B-4E illustrate one “re-filling” step (FIG. 4D) and two LT sintering steps (FIGS. 4C and 4E), it should be understood that more than one re-filling step and more than two LT sintering steps are included within the teachings of the present disclosure.

Referring to FIGS. 5A-5C, in some variations a large diameter via 137 is “seeded” before filing the large diameter via 137 with metal—metal formate slurry 150. That is, in some variations a thin layer of seed material 151 (i.e., a seed layer) is applied to a sidewall 137s and/or a bottom wall 137b of a large diameter via 137 (FIG. 5A) before the large diameter via 137 is filled with the metal—metal formate slurry 150 (FIG. 5B). For example, a thin layer of copper is formed on the sidewall 137s and/or a bottom wall 137b of a large diameter via 137 before the large diameter via 137 is filled with a copper—copper formate slurry 150 and the copper—copper formate slurry is LT sintered to form a conductive through vias 152 (FIG. 5C). In this manner, forming a conductive through via can be enhanced. Techniques or methods for forming the thin layer of seed material 151 include PVD techniques, CVD techniques, electroplating techniques, and electroless plating techniques, among others.

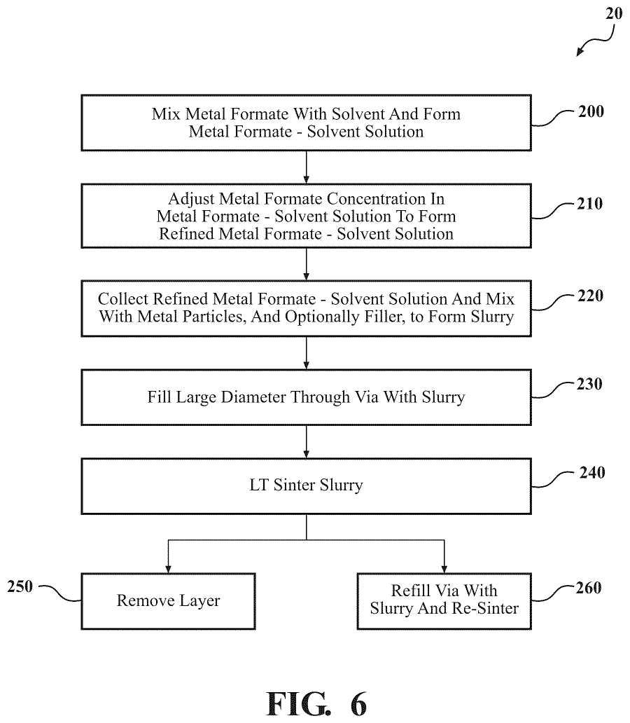

Referring now to FIG. 6, and with reference to FIGS. 3D-3G and 4B-4E, a method 30 for forming a conductive through via according to the teachings of the present disclosure includes mixing a metal formate with a solvent to form a metal formate—solvent solution at 300 and adjusting the metal formate concentration in the metal formate—solvent solution at 310 to form a refined metal formate—solvent solution. The refined metal formate—solvent solution is mixed with metal particles, and optionally a filler to form a metal formate—solvent slurry at 320, a large diameter via 137 is filled with the metal formate—solvent slurry at 330, and the metal formate—solvent slurry is LT sintered at 340, e.g., in a LT oxygen-free sintering environment/process. In some variations, a dielectric layer 135, if present, is removed at 350 such that a conductive through via 140 is formed. In the alternative, or in addition to, the large diameter vias 137 is refilled with the metal formate—solvent slurry and LT re-sintered at 360 such that a conductive through via 140 is formed.

As used herein, the phrase “refined metal formate—solvent solution” refers to a metal formate—solvent solution a concentration of metal formate such that low temperature sintering of a slurry vias formed from a plurality of metal particles mixed with the refined metal formate—solvent solution results in a sintered metal—metal formate via with less than 80 percent by volume excess reduced metal formate. For example, in some variations, a sintered metal—metal formate slurry via has less than 50 percent by volume excess reduced metal formate. And in at least one variation, a sintered metal—metal formate slurry via has less than 10 percent by volume excess reduced metal formate. And as used herein, the phrase “excess reduced metal formate” refers to reduced metal formate in a sintered metal—metal formate slurry layer that is not between and bonded to adjacent metal particles and the phrase “percent by volume” is a comparison of the volume of excess reduced metal formate to the volume of metal particles in a given sintered metal—metal formate layer. For example, in some variations, a refined metal formate—solvent solution results in less than 5% by volume excess reduced copper formate sintered metal—metal formate slurry layer formed therefrom. And in some variations, a sintered metal - metal formate slurry layer according to the teachings of the present disclosure has less than 2% by volume excess reduced metal formate, e.g., less than 1% by volume of excess reduced copper formate.

In some variations, the concentration of metal formate in the metal formate—solvent solution is reduced, e.g., using a filtering technique such as vacuum filtration, centrifugal filtration, gravity filtration, centrifugal filtration, granular filtration, mechanical filtration, and/or multilayer filtration, among others. Non-limiting examples of the metal formate include copper formate (C₂H₂CuO₄), iron formate (C₂H₈FeO₆), silver formate (CHAgO₂), and aluminum formate (Al(HCOO)₃), among others, and non-limiting examples of the solvent include isopropanolamine, cyclohexylamine, n-octyl amine, among others.

The preceding description is merely illustrative in nature and is in no way intended to limit the disclosure, its application, or its uses. Work of the presently named inventors, to the extent it may be described in the background section, as well as aspects of the description that may not otherwise qualify as prior art at the time of filing, are neither expressly nor impliedly admitted as prior art against the present technology.

The figures illustrate the functionality and operation of possible implementations of methods and systems according to various forms or variations. In this regard, each block in the block diagram may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

As used herein, the phrase at least one of A, B, and C should be construed to mean a logical (A or B or C), using a non-exclusive logical “or.” It should be understood that the various steps within a method may be executed in different order without altering the principles of the present disclosure. Disclosure of ranges includes disclosure of all ranges and subdivided ranges within the entire range.

The headings (such as “Background” and “Summary”) and sub-headings used herein are intended only for the general organization of topics within the present disclosure and are not intended to limit the disclosure of the technology or any aspect thereof. The recitation of multiple variations or forms having stated features is not intended to exclude other variations or forms having additional features, or other variations or forms incorporating different combinations of the stated features.

As used herein the term “about” when related to numerical values herein refers to known commercial and/or experimental measurement variations or tolerances for the referenced quantity. In some variations, such known commercial and/or experimental measurement tolerances are +/−10% of the measured value, while in other variations such known commercial and/or experimental measurement tolerances are +/−5% of the measured value, while in still other variations such known commercial and/or experimental measurement tolerances are +/−2.5% of the measured value. And in at least one variation, such known commercial and/or experimental measurement tolerances are +/−1% of the measured value.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . .” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

As used herein, the terms “comprise” and “include” and their variants are intended to be non-limiting, such that recitation of items in succession or a list is not to the exclusion of other like items that may also be useful in the devices and methods of this technology. Similarly, the terms “can” and “may” and their variants are intended to be non-limiting, such that recitation that a form or variation can or may comprise certain elements or features does not exclude other forms or variations of the present technology that do not contain those elements or features.

The broad teachings of the present disclosure can be implemented in a variety of forms. Therefore, while this disclosure includes particular examples, the true scope of the disclosure should not be so limited since other modifications will become apparent to the skilled practitioner upon a study of the specification and the following claims. Reference herein to one variation, or various variations means that a particular feature, structure, or characteristic described in connection with a form or variation or particular system is included in at least one variation or form. The appearances of the phrase “in one variation” (or variations thereof) are not necessarily referring to the same variation or form. It should also be understood that the various method steps discussed herein do not have to be conducted in the same order as depicted, and not each method step is required in each variation or form.

The foregoing description of the forms and variations has been provided for purposes of illustration and description. It is not intended to be exhaustive or to limit the disclosure. Individual elements or features of a particular form or variation are generally not limited to that particular form or variation, but, where applicable, are interchangeable and can be used in a selected form or variation, even if not specifically shown or described. The same may also be varied in many ways. Such variations should not be regarded as a departure from the disclosure, and all such modifications are intended to be included within the scope of the disclosure.

What is claimed is:

1. A method for fabricating a conductive through via, the method comprising:
mixing metal formate with a solvent and forming a metal formate—solvent solution;
adjusting a concentration of the metal formate—solvent solution and forming a refined metal formate—solvent solution;
mixing the refined metal formate—solvent solution with metal particles and forming a metal particle—metal formate slurry;
filling a via in a substrate with the metal particle—metal formate slurry; and
low temperature sintering the metal particle—metal formate slurry in an oxygen-free environment and forming a large diameter conductive through via in the substrate.

2. The method according to claim 1, wherein the metal formate is a copper formate.

3. The method according to claim 2, wherein the metal particles are copper nanoparticles.

4. The method according to claim 3, wherein the solvent is isopropanolamine.

5. The method according to claim 1 further comprising mixing the refined metal formate—solvent solution with a filler is selected from the group consisting of graphene, carbon nanotubes, and combinations thereof.

6. The method according to claim 5, wherein the filler comprises graphene.

7. The method according to claim 5, wherein the filler comprises carbon nanotubes.

8. The method according to claim 1, wherein the via in the substrate has an average diameter greater than 1.0 millimeter (mm) and less than about 10 mm.

9. The method according to claim 8, wherein the average diameter is less than about 5 mm.

10. The method according to claim 1, wherein the large diameter conductive through via in the substrate is an exclusive thermal conductive through via.

11. The method according to claim 1, wherein the large diameter conductive through via in the substrate is an electrically conductive through via.

12. The method according to claim 1 further comprising forming a large diameter conductive through via in a plurality of substrates.

13. The method according to claim 12, wherein the large diameter conductive through via in the plurality of substrates has a first length with a first average diameter and a second length, different than the first length, having a second average diameter different than the first average diameter.

14. The method according to claim 1 further comprises depositing a seed layer in the via before filling the via in the substrate with the metal particle—metal formate slurry.

15. The method according to claim 1, wherein the substrate is selected from the group consisting of an FR4 substrate, a silicon substrate, a glass substrate, a diamond substrate, a low-temperature co-fired ceramics (LTCC) substrate, and a high-temperature co-fired ceramics (HTCC) substrate.

16. A method for fabricating a conductive through via in a circuit board, the method comprising:
mixing copper formate with a solvent and forming a copper formate—solvent solution;
adjusting a concentration of the copper formate—solvent solution and forming a refined copper formate—solvent solution;
mixing the refined copper formate—solvent solution with metal particles and forming a metal particle—copper formate slurry;
filling a via in a circuit board substrate with the metal particle—copper formate slurry; and
low temperature sintering the metal particle—copper formate slurry in an oxygen-free environment and forming a large diameter conductive through via in the circuit board substrate.

17. The method according to claim 16, wherein the metal particles comprise copper nanoparticles.

18. The method according to claim 17 further comprising mixing the refined copper formate—solvent solution with a filler selected from the group consisting of graphene and carbon nanotubes.

19. A method for fabricating a conductive through via in a circuit board, the method comprising:
mixing copper formate with a solvent and forming a copper formate—solvent solution;
adjusting a concentration of the copper formate—solvent solution and forming a refined copper formate—solvent solution;
mixing the refined copper formate—solvent solution with copper particles and forming a copper particle—copper formate slurry;
filling a via in a circuit board substrate with the copper particle—copper formate slurry; and
low temperature sintering the copper particle—copper formate slurry in an oxygen-free environment and forming a large diameter conductive through via in the circuit board substrate.

20. The method according to claim 19 further comprising mixing a filler with the refined copper formate—solvent solution, the filler selected from the group consisting of graphene, carbon nanotubes, and combinations thereof, and wherein the large diameter conductive through via in the circuit board substrate has an average diameter greater than 2.0 millimeter (mm) and less than about 10 mm.
